(19) United States
(12) Patent Application Publication
(10) Pub. No.: US 2009/0268580 A1
(43) Pub. Date: Oct. 29, 2009

(54) MASTER RECORDING APPARATUS, MASTER RECORDING METHOD, MASTER FOR STAMPER CONTAINING HEAT-SENSITIVE RESIST MATERIAL, AND METHOD OF FORMING FILM OF HEAT-SENSITIVE

(75) Inventors: Keiichiro YUSU, Yokohama-shi (JP); Masaaki MATSUMARU, Funabashi-shi (JP); Ryosuke YAMAMOTO, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/428,986

(22) Filed: Apr. 23, 2009

(30) Foreign Application Priority Data
Apr. 25, 2008 (JP) 2008-115895

(51) Int. Cl. G11B 7/00; G11B 7/26; C23C 14/34

(52) U.S. Cl. 369/100; 369/272.1; 204/192.15; G9B/7; G9B/7.194

(57) ABSTRACT

According to one embodiment, a pit having a shape wherein the shapes of the top of a recording mark (recording start position) and the end of the recording mark (recording end position) are symmetrical can be formed on a stamper master with high reproducibility. As a result, the noise level/jitter degree of the reproduction signal obtained by reproduction from an optical disc as a final product can be reduced, thereby manufacturing at low cost the optical disc from which a signal can be stably reproduced.

### CROSS-REFERENCE TO RELATED APPLICATIONS

This application is based upon and claims the benefit of priority from Japanese Patent Application No. 2008-115895, filed Apr. 25, 2008, the entire contents of which are incorporated herein by reference.

### BACKGROUND

1. Field

One embodiment of the invention relates to an optical disc master recording apparatus, a master recording method, a master for a stamper containing a heat-sensitive resist material, and a method of forming a film of the heat-sensitive resist material for forming a pit superior in symmetry.

2. Description of the Related Art

A widespread optical disc (an information recording medium) is usually molded by means of a stamper created with a master formed of glass or a metal.

The master is usually fabricated by means of the following process.

First, a photoresist material is applied with a uniform film thickness to a glass or Si based substrate that becomes a base.

Then, a laser beam having a desired beam diameter is applied to expose a part that becomes an information pit (pre-pit, i.e., previously recorded digital information) to light.

Subsequently, the base having the information pit recorded on an entire surface thereof is developed. As a result, the part exposed to light, i.e., the part irradiated with the laser beam is dissolved out, thereby forming a concave pit (the pre-pit).

The thus formed base including the pit is used as a master to form an optical disc through a stamper fabrication process, an injection molding process, and a disc manufacturing process.

A minimum size of the pit, i.e., a minimum pit size of the optical disc master produced by the above-explained method is dependent on the wavelength of a laser beam and the numeral aperture (NA) of an objective lens since a photosensitive photoresist is used.

Therefore, when forming a smaller pit to increase recording capacity (realize high capacity), a laser beam having a shorter wavelength must be used and a lens having a higher NA must be adopted.

However, in order to achieve a higher capacity than that in a widespread optical disc conforming to the DVD standard, an ultraviolet laser beam having a wavelength of 400 nm or less or an electron beam having a shorter wavelength must be utilized.

Not only this method extremely increases a price of a manufacturing apparatus but also a fabrication margin is narrowed and a limit is produced in miniaturization of a photosensitive section (resist), and hence this method is considered to be unrealistic.

In recent years, it has been reported that phase transition mastering (PTM) using a heat-sensitive inorganic resist material is effective for overcoming the above-explained optical limit. For example, the detail is disclosed in “High resolution Blue Laser Mastering with Inorganic Photoresist, Technical Digest of ISOM/ODS202, p. 27 (Document 1).

Japanese Patent Application Publication (KOKAI) No. 2005-38752 (Document 2) discloses a method of creating a master by using a heat-sensitive resist material consisting of an inorganic material or a complex compound containing an inorganic material as a resist material and transferring a fine pit shape (pattern) onto a stamper.

However, according to the PTM technology disclosed in Document 1, trial production for stipulating conditions must be carried out many times in order to fabricate a master having a narrow pit shape margin with respect to a recording power and excellent signal characteristics with good reproducibility, and a problem still remains for practical applications.

On the other hand, even if the stamper manufacturing method disclosed in Document 2 is used, factors that should be improved are observed in regard to symmetry in a track direction (circumferentially) which are beneficial for a pit shape that can achieve a stable reproduction signal waveform with a low noise level. That is, to further reduce the noise level of the reproduction signal, the symmetry of the pit in the track direction must be further enhanced.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary diagram showing an example of a master recording apparatus to which an embodiment of the present invention is applied;

FIG. 2 is an exemplary diagram showing an example of a structure of a master on which a recording mark is formed by the master recording apparatus depicted in FIG. 1, according to an embodiment of the invention;

FIG. 3 is an exemplary diagram showing an example of a structure of the master on which the recording mark is formed by the master recording apparatus depicted in FIG. 1, according to an embodiment of the invention;

FIG. 4 is an exemplary diagram explaining a temperature profile of a resist material for the master depicted in FIGS. 2 and 3 with respect to a laser beam output in the master recording apparatus shown in FIG. 1, according to an embodiment of the invention;

FIG. 5A is an exemplary diagram explaining characteristics of a shape of the recording mark formed by the master recording apparatus depicted in FIG. 1 (an excellent mark), according to an embodiment of the invention;

FIG. 5B is an exemplary diagram explaining characteristics of a shape of a conventional recording mark compared with the recording mark depicted in FIG. 5A, according to an embodiment of the invention; and

FIG. 6 is an exemplary diagram explaining a relationship between a ratio of a complex compound and a jitter degree due to a Bi oxide in the resist material for the master to which the embodiment of the present invention is applied.

### DETAILED DESCRIPTION

Various embodiments according to the invention will be described hereinafter with reference to the accompanying drawings. In general, according to one embodiment of the invention, a master recording apparatus which records information on an optical disc master having a heat-sensitive resist film, wherein the resist film consists of at least one of a Bi oxide and a complex compound containing the Bi oxide.

Embodiments of this invention will be described in detail with reference to the drawings. The various modules of the systems described herein can be implemented as software applications, hardware and/or software modules, or components on one or more computers, such as servers. While the various modules are illustrated separately, they may share some or all of the same underlying logic or code.

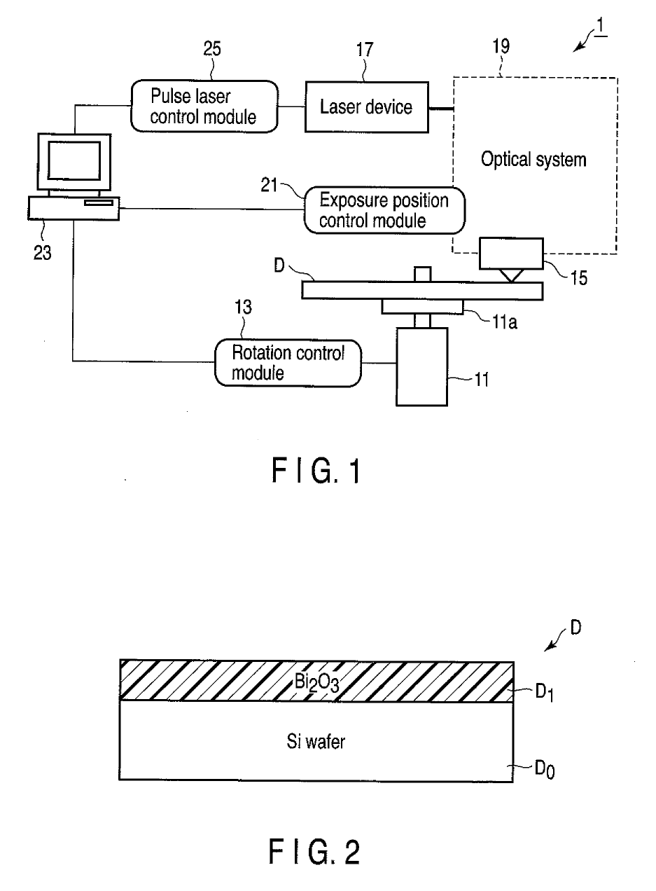

FIG. 1 shows a master recording apparatus used for the present invention.

A master recording apparatus 1 includes a spindle motor 11 that supports a glass or metal discoid base D that becomes a master and rotates the base D at a predetermined speed, a rotation control module (motor driver) 13 that controls rotation of the spindle motor 11, an objective lens 15 that records a latent image which becomes an information mark, i.e., a pit on the base D rotated by the spindle motor 11, a laser device 17 that outputs a laser beam which provides the base D with thermal energy required to record the latent image, an optical system 19 that guides the laser beam having a predetermined wavelength output from the laser device 17 to the objective lens 15, and others. It is to be noted that a rotation stage 11a that supports the base D is provided to the spindle motor 11.

Although not explained in detail, the laser device 17 is, e.g., a semiconductor laser device that can output a blue laser beam having a wavelength of 405 nm, a semiconductor laser device that can output a laser beam having a wavelength in an ultraviolet band shorter than 400 nm, or a gas laser that can output an ultrashort wavelength pulse laser beam as typified by second harmonic generation (SHG) light emission. It is to be noted that a numeral aperture NA of the objective lens 15 is 0.85 in a laser beam having a wavelength of 405 nm.

The master recording apparatus 1 also includes an exposure position control module 21 that moves the objective lens 15 and the optical system 19 radially over the base D, and a control device (control computer) 23 that controls operations (driving/stop) and others of the rotation control module 13 and the exposure position control module 21. It is to be noted that the laser device 17 controls the timing and period of laser beam output, i.e., output and stop (on/off of the laser device 17) of a laser beam through a pulse laser generation control module (laser driving circuit) 25 controlled by the control device 23.

It is to be noted that a single pulse is provided when a length of an information mark that should be recorded is the shortest unit 2T (T corresponds to one cycle of a basic clock frequency and 2T corresponds to a channel bit length in which two “1s” continue). Further, for example, a long pit like 11T is formed by applying a plurality of pulses. In order to form a smaller pit to realize a high capacity, a laser beam whose wavelength is shortened as much as possible must be combined with an objective lens having a high NA, but using a heat-sensitive resist film enables thermal formation of a small pit beyond an optical limit, especially a limit dependent on the wavelength of a laser beam.

In the above-explained master recording apparatus 1, the glass or Si based substrate D on which a heat-sensitive resist material is formed with a predetermined thickness is rotated at a predetermined speed by the rotation stage 11a, i.e., the spindle motor 11. The optical disc 100 is rotated at a predetermined velocity by a spindle motor 63.

Although not explained in detail, when a resist film (the resist material) on the base D rotated at the predetermined speed is irradiated with a laser beam which is turned on/off by means of a pulse generated through an arbitrary waveform generation device or a formatter, a latent image corresponding to information for which a concave portion should be formed in the resist film as recorded information, i.e., a pit is recorded on a surface, i.e., the resist film of the base D. That is, the laser beam is converged to have a predetermined spot size by the objective lens 15 and applied to the resist film on the base D. As a result, a temperature of the resist film at a portion irradiated with the laser beam is increased, and the latent image is formed. Furthermore, when the optical system 19 (the objective lens 15) is moved radially over the base D through the exposure position control module 21 while (in a period where) the laser beam is applied, the latent image is formed into a concentric shape or a spiral shape that a rotation angle and a radial position continuously vary.

It is to be noted that the information mark (the pit) recorded as the latent image on the resist film is of a positive type in many cases. For example, when the information mark is developed by an alkali developer having pH of approximately 12 to 14, it is dissolved out in the developer to become a concave portion. Therefore, an information mark in a stamper created from the base D has a convex shape. As a result, an information mark in an optical disc formed from the finished stamper becomes a concave pit (hole shape).

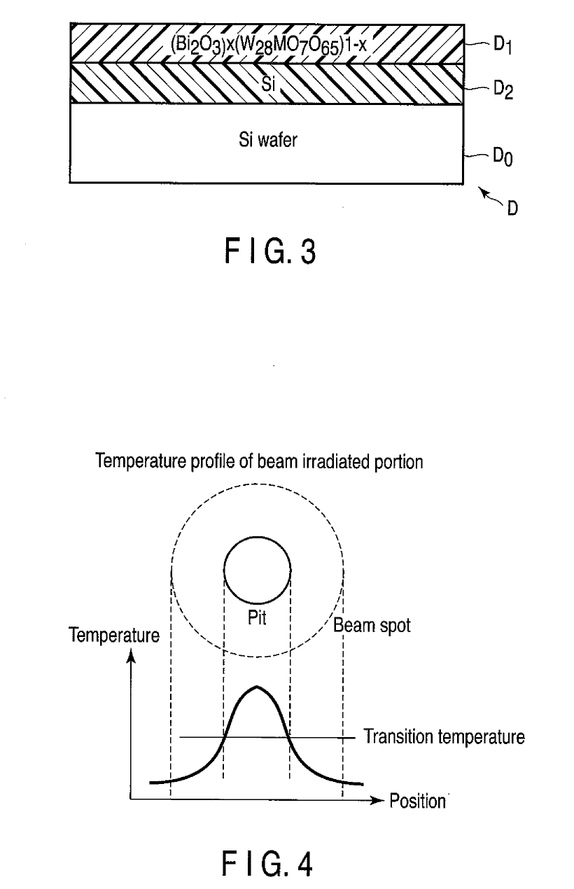

For example, as shown in FIG. 2 or 3, the base D has a structure where a resist film D1 consisting of, e.g., Bi₂O₃ or (Bi₂O₃)×(W₂₈Mo₇O₆₅)1-x is formed with a predetermined film thickness on an Si (silicon) wafer (an Si substrate) Do having a predetermined thickness, and has a precipitous temperature profile as shown in FIG. 4. That is, in the resist film using Bi₂O₃ or (Bi₂O₃)×(W₂₈Mo₇O₆₅)1-x, a size (region) of a portion whose temperature is increased beyond a transition temperature of the resist film is smaller than a size of a laser irradiated portion to which the laser beam is applied (condensed).

Therefore, a portion smaller than the beam diameter mainly determined according to optical conditions, i.e., the wavelength λ of the laser beam and the NA of the objective lens 15, can be transferred and transformed in a limited way. Therefore, a small pit can be eventually formed.

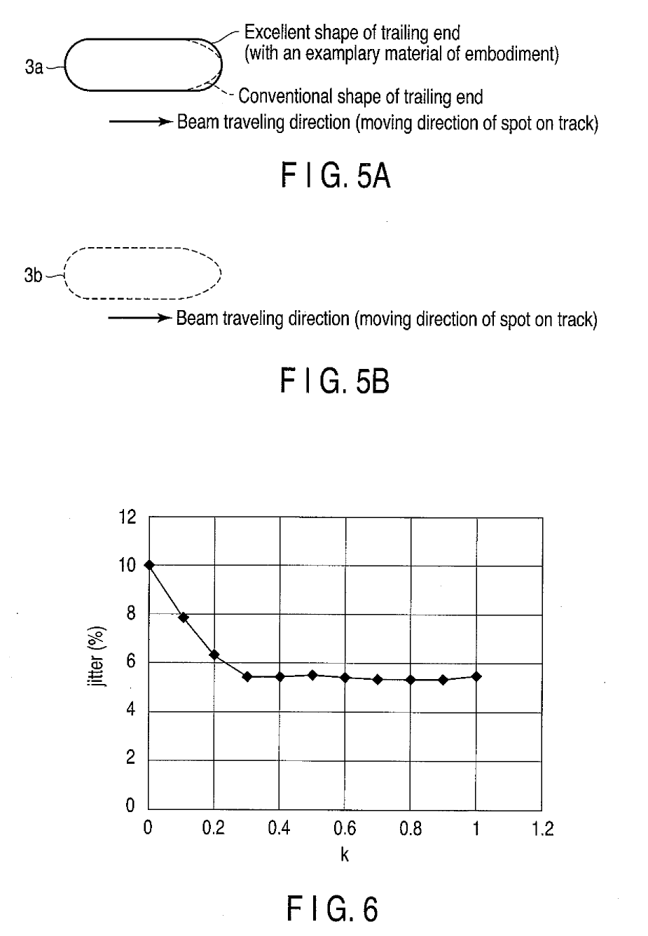

Moreover, since the resist film using Bi₂O₃ or (Bi₂O₃)×(W₂₈Mo₇O₆₅)1-x has such a precipitous temperature profile as shown in FIG. 4, an influence of thermal diffusion is small as compared with a resist film formed of a resist material adopted in a conventional example, and hence an edge-like portion or a recrystallized region involved by remaining heat or thermal diffusion is rarely generated around the pit after application of the laser beam is stopped as shown in FIG. 5A (in a shape of mark is excellent). Therefore, as shown in FIG. 5B, it is possible to eliminate the problem that the shape of the end of the pit is different from the shape of the top of the pit (symmetry is reduced), which is caused when application of the laser beam is stopped earlier than that for the end of the pit to be formed.

That is, considering the symmetry of the shapes of the top and the end of the pit in a beam traveling direction, it has been confirmed in various optical discs previously manufactured that the noise level or the degree (level) of jitter of the reproduction signal obtained by reproducing a signal from an optical disc actually manufactured by a stamper using the base D is reduced as the symmetry is increased. It is to be noted that, since it can be explained that a spot of the laser beam applied to a predetermined radial position on the base D seems to move on the resist film of the base D when the base D is rotated orthogonally to the radius of the base D which is generally called a track direction, the beam traveling direction is widely used.

Therefore, when the symmetry of the shapes of the top and end of the pit (previously formed information mark) formed on the master D in the track direction are high, not only can the recording density be improved but also the reproduction signal can be stably acquired.

It is to be noted that a pit shape on the optical disc master D fabricated by the master recording apparatus 1 and the master recording method demonstrates excellent symmetry. Additionally, it is also superior in recording sensitivity, thereby enabling high-speed recording.

In more detail, the master recording apparatus 1 and the master recording method using this apparatus form a pit on the resist film by irradiating the resist film prepared on the base D in advance with a laser beam and selectively heating the resist film, and they are characterized in that the resist film consists of a Bi oxide and a complex compound containing the Bi oxide.

It is preferable for the other material combined with the Bi oxide to be an oxide containing at least one of W, Mo, Nb, Ta, Cr, V, Ti, Zr, and Hf.

It is to be noted that a thickness of the resist film formed of a Bi oxide or a complex compound of an oxide containing at least one of W, Mo, Nb, Ta, Cr, V, Ti, Zr, and Hf and the Bi oxide on the glass substrate or the Si substrate preferably falls within the range of 10 to 200 nm. Further, as a method of forming the resist film, a general physical evaporation method (as typified by an RF magnetron sputtering method or a DC magnetron sputtering method) can be used.

Furthermore, when the heat-sensitive resist film is used, since thermophysical properties, e.g., thermal conductivity or thermal capacity are important, an intermediate layer may be interposed between the base and the resist film to control heat conduction.

It is to be noted that, when the intermediate layer is interposed, when the intermediate layer having low thermal conductivity is interposed to increase thermal sensitivity, a greater effect can be obtained. As intermediate layer materials each having low thermal conductivity, there are, e.g., Si, various kinds of silicides, SiO₂, ZnS, and compounds containing these materials.

Furthermore, the thermal sensitivity of the resist film can be adjusted by changing the film formation conditions or the film thickness of the intermediate layer. On the other hand, in light of suppression of delamination (of the intermediate layer) from the base due to internal stress, it is preferable for the film thickness of the intermediate layer to be 200 nm or less.

Therefore, the heat-sensitive resist film according to the present invention consists of an inorganic material and is constituted of one layer or two layers having a total film thickness of 400 nm or less.

Specific examples according to the present invention will be described hereinafter to explain the present invention in more detail.

### EXAMPLE 1

A heat-sensitive resist film consisting of Bi₂O₃ and having a thickness of 80 nm was formed on an Si wafer having a diameter of eight inches and a thickness of 0.7 mm by a DC magnetron sputtering method (the concept of a cross-sectional direction is the same as that in the example depicted in FIG. 2).

When a laser beam having a wavelength of 405 nm was recorded on this resist film with a linear velocity of 5.3 m/s and a reference clock frequency of 66 MHz while changing a power of the laser beam in the range of 1 to 5 mW by means of an objective lens 15 having a numerical aperture (NA) of 0.85, a recorded portion was crystallized. It is to be noted that a track pitch is 0.32 μm.

As a recorded pattern, for example, (n-1) pulses were applied with respect to an arbitrary mark length nT (T corresponds to one cycle of the basic clock frequency) to record a random pattern. At this time, the recorded portion was crystallized.

The recorded wafer (base D) was immersed in an inorganic alkali developer tank having pH of 12.7 for 120 seconds and then rinsed with pure water.

Observing a surface of the wafer (the base D) by means of atomic force microscopy (AFM), it was confirmed that a recording mark remained as a concave portion (i.e., a concave pit was formed as the recording mark) and a positive etching behavior with the recorded portion dissolved out was demonstrated.

Nickel having a thickness of 40 nm was DC-sputtered on a surface of the wafer (the base D) after etching, the wafer was used as a negative electrode and immersed in an aqueous nickel sulfamate solution, and a predetermined current/voltage was applied while waiting for nickel to be deposited.

After approximately one hour, a nickel foil having a thickness of 250 μm was deposited and it was delaminated.

It was confirmed by means of AFM observation that the recording mark was transferred to a delaminated nickel stamper as a convex portion. It should be noted that both ends of a 4T mark were observed in detail, and it was found that each of both ends has a semicircular shape having the same curvature and a height of 60 nm.

It was revealed that the stamper obtained from the master fabricated by the master recording apparatus and the master recording method according to the present invention in this manner has a convex pit shape in which the shape of the top of a recording mark (recording start position) and the shape of the end of the recording mark (recording end position) are symmetrical.

A polycarbonate (PC) substrate having a thickness of 1.1 mm was molded by means of this stamper, then a reflection film was formed, and another PC having a thickness of 0.1 mm was further attached to this substrate to obtain an optical disc having a thickness of 1.2 mm.

As a result of evaluating this disc having a recording capacity of approximately 25 GB by means of an evaluation apparatus ODU-1000, an excellent result, i.e., a power of 1.5 mW and jitter of 6.4%, was obtained.

It was revealed that the optical disc having a recording capacity of 25 GB can be fabricated by combining a blue semiconductor laser having a general wavelength of 405 nm with an objective lens having an NA of 0.85 for the optical disc fabricated by means of the master formed by the master recording apparatus and the master recording method according to the present invention as explained above.

### EXAMPLE 2

An Si layer having a film thickness of 90 nm was formed on an Si wafer (master (substrate) D) having a diameter of eight inches and a thickness of 0.7 mm by means of a DC magnetron sputtering method, and then Bi₂O₃ and W₂₈Mo₇O₆₅ were simultaneously sputtered by again using the DC magnetron sputtering method to form a film of (Bi₂O3)×(W₂₈Mo₇O₆₅)1-x having a thickness of 80 nm (the concept of a cross-sectional direction is the same as that in the example depicted in FIG. 3). Here, x represents an atomic ratio of Bi₂O₃. In this example, x was changed in the range of 0≦x≦1.0 at intervals of 0.1 to form a resist film. The (Bi₂O3)×(W₂₈Mo₇O₆₅)1-x after film formation was amorphous, and a recorded portion was crystallized when recording was performed under the same recording conditions as those in Example 1.

When development was carried out under the same conditions as those in Example 1, a positive etching behavior that the recorded portion is dissolved out and a concave pit remains was demonstrated. Then, processing from a stamper fabrication process to a disc manufacturing process was effected under the same conditions as those in Example 1.

Observing by means of AFM a convex pit transferred to a stamper, there was observed a convex pit having a shape wherein the atomic ratio of Bi₂O₃ is 0.1≦x≦1.0 and the shape of the top of a recording mark (recording start position) and the shape of the end of the recording mark (recording end position) are symmetrical, i.e., a shape which can be determined to be substantially symmetrical. It is to be noted that, when a ratio of W₂₈Mo₇O₆₅ is “0”, this is the same as Example 1, and no problem occurs.

FIG. 6 shows a result of evaluating an obtained optical disc by an evaluation apparatus ODU-1000 as a function of x.

As apparent from FIG. 6, there was obtained a very excellent result that a jitter is 8% or less when x is 0.1 or greater, especially a jitter is 6% or less when x is 0.3 or greater.

As explained above, it was revealed that an optical disc master having a recording medium of 25 GB can be fabricated by means of the master recording apparatus and the master recording method according to the present invention as explained above to combine a blue semiconductor laser having a general wavelength of 405 nm with an objective lens having an NA of 0.85.

### EXAMPLE 3

A film of Si was formed with a thickness of 100 nm and a film of (Bi₂O₃)0.5(W₂₈Mo₇O₆₅)0.5 was further formed with a thickness of 80 nm on the Si film by the same method as that in Example 2.

The (Bi₂O₃)0.5(W₂₈Mo₇O₆₅)0.5 after film formation was amorphous.

A laser beam having a wavelength of 405 nm was applied with linear velocities of 5.3, 10.6, and 15.9 m/s corresponding to a single speed (1×) to a triple speed (3×) to record random patterns on this resist film by means of an optical system (an objective lens) having an NA of 0.85.

When development was performed under the same conditions as those in Example 1, a positive etching behavior that a recorded portion is dissolved and a concave pit remains was demonstrated.

Thereafter, processing from a stamper fabrication process to a disc manufacturing process was effected under the same conditions as those in Example 1.

Observing by means of AFM a convex pit transferred to a stamper, there was observed a convex pit having a shape wherein the shape of the top of a recording mark (recording start position) and the shape of the end of the recording mark (recording end position) are symmetrical, i.e., a shape which can be determined to be substantially symmetrical at any linear speed conditions like Example 1.

As a result of evaluating an obtained disc by the same method as that in Example 1, a jitter was 5.8% in case of 1× recording, it was 6.1% in case of 2× recording, and it was 6.2% in case of 3× recording.

According to this embodiment, it was revealed that an information mark (pit) can be recorded without problems even if a master recording speed is greatly increased. This implies that a master recording time can be greatly shortened, which is effective for reducing a cost for manufacturing the optical disc.

It is to be noted that a Bi (bismuth) oxide used for a resist material in the present invention is a material that has a melting point of 870° C. and can be crystallized at approximately 200° C. The Bi oxide becomes amorphous because of quenching by means of a general physical vapor deposition method at the time of film formation.

Further, the Bi (bismuth) oxide used for a resist material enables recording of a recoding mark with high sensitivity as compared with an example using a transition metal oxide which has been conventionally widely adopted as explained above.

It is to be noted that, when a complex compound consisting of an oxide containing at least one of W, Mo, Nb, Ta, Cr, V, Ti, Zr, and Hf and the Bi oxide is used, sensitivity is reduced as compared with an example using the Bi oxide alone, but the symmetry of the shapes of the writing start position (recording start position) of a pit (recording mark) and the end (recording end position) of the recording mark can be improved by means of the temperature profile of the beam irradiation portion, which has been explained in conjunction with FIG. 4.

When this resist film is irradiated with a laser beam, it is crystallized after a melted state or crystallized while maintaining a solid-phase state. That is, a latent image corresponding to information that should be recorded is recorded in the resist film.

Since the resist film is of a positive type, when the latent image formed in the resist film is developed by an alkali developer, a resist material in a latent image portion is dissolved out to form a concave portion (pit). Therefore, a stamper produced with this resist film being used as a master has a convex pit.

This convex pit becomes a convex pit having a shape wherein the shapes of the top of a recording mark (recording start position) and the end of the recording mark (recording end position) are symmetrical, i.e., a shape that can be determined to be substantially symmetrical, and it is beneficial for a reduction in the noise level/jitter degree of the reproduction signal reproduced from an optical disc which is a final product.

When one of the embodiments according to the present invention is used as explained above, a pit having a shape wherein the shapes of the top of a recording mark (recording start position) and the end of the recording mark (recording end position) are symmetrical, i.e., a shape that can be determined to be substantially symmetrical can be formed with high reproducibility with respect to a master used for fabrication of a stamper that is utilized for formation of an optical disc as a final product. Therefore, the noise level/jitter degree of the reproduction signal obtained by means of reproduction from the optical disc as the final product can be reduced, thereby manufacturing at low cost the optical disc from which a signal can be stably reproduced. That is, using one of the embodiments according to the present invention allows fabrication of a master which does not have an edge around a pit specific to a heat-sensitive resist and has a pit (pre-pit) having a shape wherein the shapes of the top of a recording mark (recording start position) and the end of the recording mark (recording end position) are symmetrical at the time of fabricating the master by using a heat-sensitive resist material.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A master recording apparatus configured to record information on an optical master disc comprising a heat-sensitive resist film, wherein the resist film consists of at least one of a bismuth (Bi) oxide and a complex compound comprising the Bi oxide.

2. The apparatus of claim 1, wherein the optical master disc comprising an underlying layer configured to control thermophysical properties comprising at least one of heat conduction and a heat capacity between the resist film and a substrate.

3. The apparatus of claim 1, wherein the complex compound comprising the Bi oxide in the resist film comprises at least one of Tungsten (W), Molybdenum (Mo), Niobium (Nb), Tantalum (Ta), Chromium (Cr), Vanadium (V), Titanium (Ti), Zirconium (Zr), and Hafnium (Hf).

4. The apparatus of claim 2, wherein the complex compound comprising the Bi oxide in the resist film comprises at least one of W, Mo, Nb, Ta, Cr, V, Ti, Zr, and Hf.

5. A master recording method of recording information on an optical master disc comprising a heat-sensitive resist film, wherein the resist film consists of a Bi oxide and a complex compound comprising the Bi oxide, the master recording method comprising:
forming a recording mark corresponding to two cycles of a fundamental clock frequency by heating with one-time irradiation of light wherein one cycle of the fundamental clock frequency is determined as “1”.

6. The method of claim 5, wherein the optical master disc comprises an underlying layer configured to control thermophysical properties comprising at least one of heat conduction and a heat capacity between the resist film and a substrate.

7. The method of claim 5, wherein the complex compound comprising the Bi oxide in the resist film comprises at least one of W, Mo, Nb, Ta, Cr, V, Ti, Zr, and Hf.

8. The method of claim 6, wherein the complex compound comprising the Bi oxide in the resist film comprises at least one of W, Mo, Nb, Ta, Cr, V, Ti, Zr, and Hf.

9. An optical master disc for creating a stamper used in manufacturing an optical disc comprising:
a substrate comprising either glass or metal; and
a resist film comprising at least one of a Bi oxide and a complex compound comprising a Bi oxide with a predetermined thickness on the substrate.

10. The master disc of claim 9, wherein the resist film comprises an amorphous shape after simultaneously sputtering the Bi oxide and the complex compound comprising a Bi oxide.

11. The mater disc of claim 9, wherein the complex compound comprising the Bi oxide in the resist film comprises at least one of W, Mo, Nb, Ta, Cr, V, Ti, Zr, and Hf.

12. The master disc of claim 10, wherein the complex compound comprising the Bi oxide in the resist film comprises at least one of W, Mo, Nb, Ta, Cr, V, Ti, Zr, and Hf.

13. A method of creating an optical master disc used for creating a stamper used in manufacturing an optical disc, comprising:
simultaneously sputtering a Bi oxide and a complex compound comprising the Bi oxide with respect to a substrate; and
quenching the Bi oxide into an amorphous shape.
